(19) United States
(12) Patent Application Publication
(10) Pub. No.: US 2024/0247386 A1
(43) Pub. Date: Jul. 25, 2024

(54) DURABLE, LOW LOADING OXYGEN EVOLUTION REACTION CATALYSTS AND METHODS OF FORMING SUCH CATALYSTS

(71) Applicant: ELECTRIC HYDROGEN CO., Natick, MA (US)

(72) Inventors: Raffi M. GARABEDIAN, Los Altos, CA (US); Timothy J. KUCHARSKI, Belmont, MA (US)

(21) Appl. No.: 18/684,028

(22) PCT Filed: Dec. 13, 2022
(86) PCT No.: PCT/US2022/052621

§ 371 Date: Feb. 15, 2024

Related U.S. Application Data
(60) Provisional application No. 63/289,761, filed on Dec. 15, 2021.

(51) Int. Cl. C25B 11/069; C23C 16/40; C23C 16/455; C25B 11/056; C25B 11/075; D06M 10/06; D06M 101/30

(52) U.S. Cl. CPC C25B 11/069; C23C 16/40; C23C 16/45555; C25B 11/056; C25B 11/075; D06M 10/06; D06M 2101/30

(57) ABSTRACT

The following disclosure relates to catalyst compositions for electrochemical cells and their methods of making. In one example, the method includes providing a supporting substrate and depositing an active catalyst composition onto a surface of the supporting substrate via atomic layer deposition (AID). A catalyst composition includes a conductive substrate and an active catalyst deposited on a surface of the conductive substrate via atomic layer deposition.

This application claims the benefit of U.S. Provisional Patent Application No. 63/289,761, filed Dec. 15, 2021, which is hereby incorporated by reference in its entirety.

### FIELD

The following disclosure relates to electrochemical or electrolysis cells and components thereof. More specifically, the following disclosure relates to oxygen evolution reaction catalysts used in such electrolysis cells.

### BACKGROUND

An electrochemical or electrolysis cell or system uses electrical energy to drive a chemical reaction. For example, within a water splitting electrolysis reaction within the electrolysis cell, water is split to form hydrogen and oxygen. The products may be used as energy sources for later use. In recent years, improvements in operational efficiency have made electrolyzer systems competitive market solutions for energy storage, generation, and/or transport. For example, the cost of generation may be below $10 per kilogram of hydrogen in some cases. Increases in efficiency and/or improvements in operation will continue to drive installation of electrolyzer systems.

For example, various challenges are present with operation at the PEM of an electrolysis cell. These challenges are not well described within the literature and are not fully appreciated in the field. For example, at the interface, a 4- or 5-fold junction is required at which a catalyst (e.g., IrOx catalyst) is supplied with water and electricity. Additionally, at the interface, protons and gas need to be removed. In other words, an electrolysis cell requires a 5-way interface between catalyst, water, electrical conductor, proton transport, and bubble formation/gas transport. However, this need for multiple interfaces is not fully appreciated in the literature and as a result the requirement is not well incorporated into existing state-of-the-art PEM systems. The current best-in-class commercial PEM electrolyzers do not have interfaces designed to optimize the transport and fluxes outlined above.

The central PEM/catalyst/water/gas interface is accomplished by randomly coating a catalyst and PEM material (ionomer) onto one or both of a Proton Exchange Membrane (PEM) layer plus a porous gas diffusion layer (GDL) that permits liquids and gases to flow through the holes while the solid material conducts electricity. The PEM layer and the GDL are then joined with the hope that the desired multi-way junctions are present. This is especially problematic for the anode GDL. The anode side is traditionally the rate-limiting reaction, owing to slower catalyst kinetics and the requirement for larger overpotential. Moreover, because the anode GDL sits in an oxidizing acidic environment, it is typically made of platinum-coated titanium. Titanium is a poor conductor, and the platinum is very expensive.

Therefore, there is a desire to improve the interface to improve electrical conductivity and increase the density of “5-way junctions” and reduce costs, while maintaining fluid flow and bubble/gas removal.

In a PEM electrolyzer, iridium oxide is an example of a high performance catalyst used to promote the oxygen evolution reaction. Iridium is extremely rare and expensive. As such, the cost of electrolyzers is sensitive to the amount of iridium used. In addition, the scale of the PEM electrolyzer industry could become constrained by global iridium availability. Reducing the amount of iridium used may limit the operating lifetime of the electrolyzer as the catalyst has a tendency to degrade with use over time. As such, there remains a need to develop an improved oxygen evolution reaction catalyst with a reduced catalyst loading while maintaining operating performance or lifetime of the catalyst/electrolyzer.

### SUMMARY

In one embodiment, a method of depositing an active catalyst composition on a surface of a substrate includes providing a supporting substrate and depositing an active catalyst composition onto a surface of the supporting substrate via atomic layer deposition (ALD).

In another embodiment, a catalyst composition includes a conductive substrate and an active catalyst deposited on a surface of the conductive substrate via atomic layer deposition.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

Exemplary embodiments are described herein with reference to the following drawings.

FIG. 1 depicts an example of an electrolytic cell.

FIG. 2 depicts an additional example of an electrolytic cell.

FIG. 3 depicts an example of an IrOx catalyst coated or added to a surface of a spherical or particulate substrate.

FIG. 4 depicts an example of a configuration of electrical contact in the context of a membrane electrochemical system.

FIG. 5 depicts an example of an improved electrochemical catalyst composition having an electrically conductive nanofiber core and an atomic-scale (e.g., nanometer-scale) layer of active components (e.g., iridium oxide) on the surface of the core.

FIG. 6 depicts an example of an example of the improved catalyst composition from FIG. 5 within the context of a membrane electrochemical system.

FIG. 7 depicts examples of various IrOx loading curves.

### DETAILED DESCRIPTION

Improved catalyst compositions and their methods of making are disclosed in the various sections below. These catalyst compositions may be used in the production of hydrogen from water and electricity (an oxygen evolution reaction catalyst). Alternatively, the catalyst may be used within a hydrogen electrolysis cell, or another electrochemical cell such as a CO₂ reduction cell, NH₃ production cell, or a fuel cell.

As noted above, there is a desire to develop an improved, lower cost catalyst for an electrochemical cell in which there is reduction the amount of active catalyst required per unit area of electrolyzer membrane without compromising the catalyst lifetime or performance.

### Electrochemical Cells

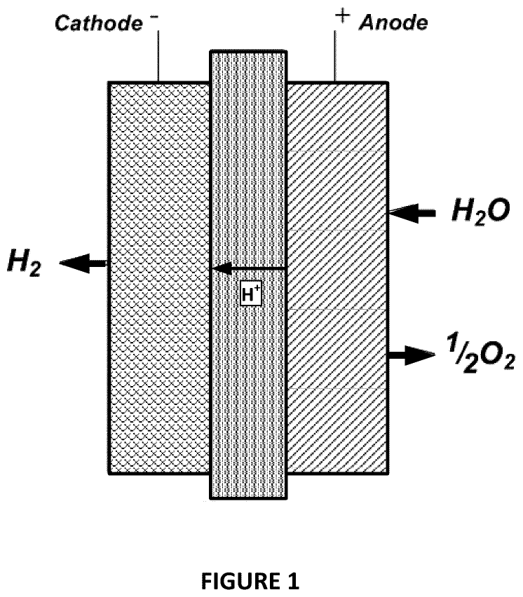

FIG. 1 depicts an example of an electrochemical or electrolytic cell for hydrogen gas and oxygen gas production through the splitting of water. The electrolytic cell includes a cathode, an anode, and a membrane positioned between the cathode and anode. The membrane may be a catalyst coated membrane (CCM) such as a proton exchange membrane (PEM). Proton Exchange Membrane (PEM) electrolysis involves the use of a solid electrolyte or ion exchange membrane. Within the water splitting electrolysis reaction, one interface runs an oxygen evolution reaction (OER) while the other interface runs a hydrogen evolution reaction (HER). For example, the anode reaction is H₂O→2H⁺+½O₂+2e and the cathode reaction is 2H⁺+2e→H₂.

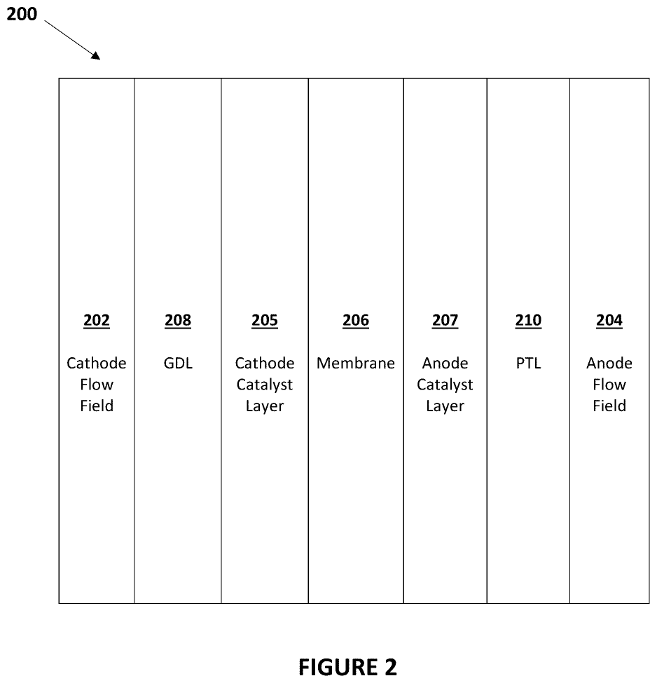

FIG. 2 depicts an additional example of an electrochemical or electrolytic cell. Specifically, FIG. 2 depicts a portion of an electrochemical cell 200 having a cathode flow field 202, an anode flow field 204, and a membrane 206 positioned between the cathode flow field 202 and the anode flow field 204.

In certain examples, the membrane 206 may be a catalyst coated membrane (CCM) having a cathode catalyst layer 205 and/or an anode catalyst layer 207 positioned on respective surfaces of the membrane 206. As used throughout this disclosure, the term “membrane” may refer to a catalyst coated membrane (CCM) having such catalyst layers.

In certain examples, additional layers may be present within the electrochemical cell 200. For example, one or more additional layers 208 may be positioned between the cathode flow field 202 and membrane 206. In certain examples, this may include a gas diffusion layer (GDL) 208 may be positioned between the cathode flow field 202 and membrane 206. This may be advantageous in providing a hydrogen diffusion barrier adjacent to the cathode on one side of the multi-layered membrane to mitigate hydrogen crossover to the anode side.

In certain examples, the GDL is made from a carbon paper or woven carbon fabrics. The GDL is configured to allow the flow of hydrogen gas to pass through it. The thickness of the GDL may be within a range of 100-1000 microns, for example. The thickness may affect the mass transport within the cell as well as the durability/deformability and electrical/thermal conductivity of the GDL. In other words, a thinner GDL may provide better mass transport, lower resistance, and a reduction in durability (e.g., greater chance for localized deformation).

Similarly, one or more additional layers 210 may be present in the electrochemical cell between the membrane 206 and the anode 204. In certain examples, this may include a porous transport layer (PTL) positioned between the membrane 206 (e.g., the anode catalyst layer 207 of the catalyst coated membrane 206) and the anode flow field 204.

In certain examples, the PTL is made from a titanium mesh/felt. Similar to the GDL, the PTL is configured to allow the transportation of the reactant water to the anode catalyst layers, remove produced oxygen gas, and provide good electrical conductivity for effective electron conduction. The thickness of the PTL may be within a range of 100-1000 microns, for example. The thickness may affect the mass transport within the cell as well as the durability/deformability and electrical/thermal conductivity of the PTL. In other words, a thinner PTL may provide better mass transport and a reduction in durability (e.g., greater chance for localized deformation).

In some examples, an anode catalyst coating layer may be positioned between the anode 204 and the PTL.

The cathode 202 and anode 204 of the cell may individually include a flow field plate composed of metal, carbon, or a composite material having a set of channels machined, stamped, or etched into the plate to allow fluids to flow inward toward the membrane or out of the cell.

### Catalyst Compositions for Catalyst Coated Membranes

Active sites of a heterogeneous catalyst are at an interface of the catalyst material and the surrounding media, leaving the subsurface volume of catalyst inaccessible and unused.

In some cases, PEM electrolyzer oxygen evolution reduction catalysts are made by dispersing homogeneous particles of iridium oxide (IrOx) (sometimes also blended with other PGM components like ruthenium) into an ink which is applied to a membrane surface. In some cases, the IrOx may be adhered to the surface of conductive carriers such as electrospun conductive oxide fibers. In other cases, thin layers of IrOx are functionalized on the surface of large conjugated organic molecules. These advanced catalyst approaches provide one approach for reducing catalyst loading and activity, though they still leave significant room for further improvement.

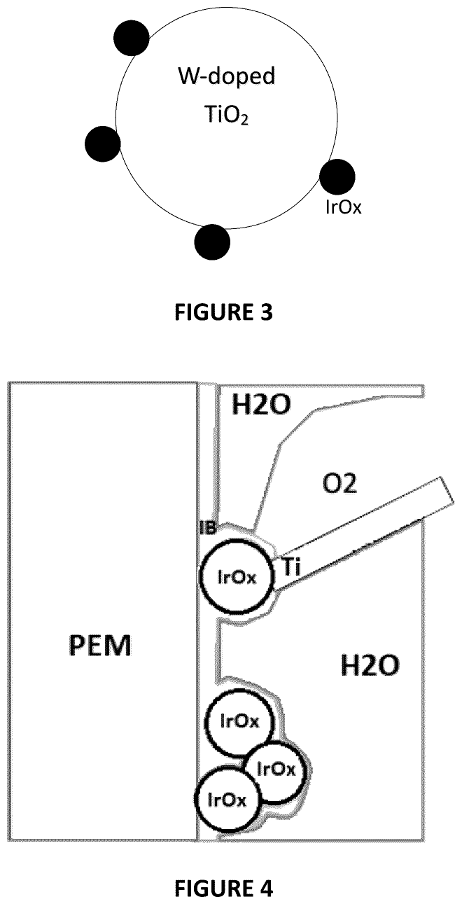

In certain embodiments, an IrOx catalyst is coated or added to a surface of a spherical or particulate substrate (e.g., a W-doped TiO₂ substrate), as depicted in FIG. 3.

These solutions are expensive to produce or do not adequately reduce the iridium loading without compromising current density performance and durability. The nature of catalysts is that they only possess surface activity. Any precious active materials that are in bulk form (even on the interior of a nanoparticle) and not accessible on a surface are wasted as they are unavailable to participate in the desired chemical reactions. In addition, many surface functionalized catalysts exhibit poor chemical bonding and adhesion of the precious metal species to the supporting substrate surfaces, resulting in durability challenges.

FIG. 4 depicts a configuration of electrical contact in the context of a membrane electrochemical system (in this case proton exchange membrane water electrolysis).

As depicted in FIG. 4, the electrochemical system includes a 5-way interface between catalyst (IrOx), water (H₂O), electrical conductor (Ti), proton transport (PEM), and bubble formation/gas transport (O₂). A single metallic titanium fiber (Ti) represents the electrical conductor or electron conduction to a catalyst site on a catalyst coated proton exchange membrane (PEM) or proton transport. The spherical iridium oxide (IrOx) particles represent the catalyst sites of the system.

Further, an ionomeric binder (IB) represents the location where the IrOx particles form the catalyst coating on the PEM surface. The combination may be referred to as a Catalyst Coated Membrane (CCM). Note that some of the IrOx catalyst is not accessed by the metallic Ti electrical contact. Though mechanisms exist for electron transport between closely coupled conductive particles, these operate at short length scales far smaller than the typical spacing of practical metallic contacts to the CCM unless catalyst particle loading is extremely high and hence inefficient.

One approach to improve catalyst utilization is the use of nanostructured core-shell particles where a very thin (e.g., mono layer) shell of active catalyst is applied to a suitable carrier substrate selected for desirable properties such as size distribution, surface morphology, chemical stability, electrical conductivity, etc.

A good electrochemical catalyst must be present in high quantities at the junction of chemical species and electrons. In order to maximize charge transport to the available catalyst surface, it is desirable to build structures of large conducting carriers coated with very thin layers of catalyst. In certain examples, the structures may provide for high active surface area of particles with morphology that provides for a tightly interconnected network that facilitates electron conduction. One conventional approach has been to electrospin fibers of the catalyst material (see, e.g., “Recent Advances in 1D Electrospun Nanocatalysts for Electrochemical Water Splitting.” Small Structures 2, no. 2 (2021): 2000048.https://doi.org/10.1002/sstr.202000048), but this wastes a great deal of the catalyst material in the core of the structure. A better alternative, and the focus of this disclosure, is to produce an electrochemically stable and inexpensive conductive base material and to coat the surface of the “core” with “shell” or thin, nanometer-level of electroactive catalyst.

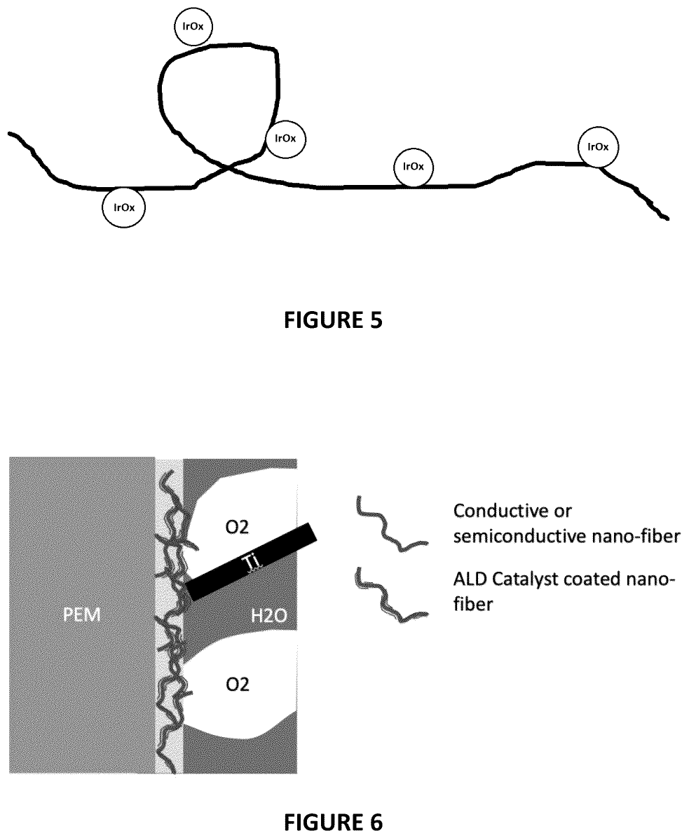

FIG. 5 depicts an example of such an improved electrochemical catalyst composition. The composition includes an electrically conductive nanofiber core (e.g., wire) and an atomic-scale (nanometer-scale) layer of active components on the surface of the wire (e.g., spheres of IrOx).

FIG. 6 depicts the improved catalyst composition within the context of a membrane electrochemical system.

The improved configurations disclosed in FIGS. 5 and 6 herein would be to provide an elongated, thin conductor (e.g., a thin filament or wire) core or substrate. An electrospun material could be used to form the elongated fibrous conductor. The catalyst (e.g., IrOx or a conducting polymer mixed with the IrOx nanoparticles) could be deposited or added to the surface of the filament/wire/elongated conductor.

This is advantageous over the spherical or particulate substrate in that the long conductor arrangement may provide improved electron transport to the catalyst nanoparticle. As such, due to the improved electron transport, a lower catalyst loading could be provided to the long conductor to provide similar or improved performance properties.

### Methods of Deposition of Catalyst on Substrate

In certain examples, particle atomic layer deposition may be used to deposit a thin layer or shell of active catalyst on a suitable substrate. In alternative examples, another technique such as chemical vapor deposition may be employed to provide the nanometer-level of active catalyst on the substrate.

Atomic Layer Deposition (ALD) is used in a range of industries because it allows the deposition of ultrathin films of material or combinations of materials with control of the material thickness at the monolayer level. Techniques are available for ALD on solid substrates as well as on powder substrates (called powder ALD). Powder ALD is used for the construction of core-shell material and surface modified powders for use in energy storage devices such as lithium-ion batteries for example. It is also well studied as a process for the formation of engineered catalysts.

Particle ALD is a known and available method of applying extremely thin atomic-scale layers of materials (often called “shells”) onto particles (called “cores”). Particle ALD is being developed and used for the production of engineered materials in the field of batteries (e.g., Li-ion batteries) and chemical catalysts among others.

By using ALD to deposit such thin films of active catalyst compositions on specifically selected support materials, the fraction of chemically and electrically accessible material in the catalyst layer (concentrating the catalyst on nano-fibrous surfaces and interconnecting those fibers in an electrically continuous network) may be increased, allowing the overall loading of catalyst to be significantly reduced while maintaining a high specific activity.

In certain examples, the thickness of the layer of active catalyst being deposited on a surface of the substrate is on a nanometer-level thickness. For example, the thickness of the layer of active catalyst deposited is in a range of 0.1-100 nm, 1-100 nm, 0.1-10 nm, or 1-10 nm.

### Active Catalysts Being Deposited

In certain examples, particle ALD techniques may be used to apply nanometer (nm)-scale layers (or alternatively nm-scale islands) of active catalyst to particle support structures for use in electrochemical cells.

In certain examples, the active catalyst composition being deposited on the surface of a suitable substrate includes at least one metal oxide. The metal oxide may be a transitional metal oxide such as iridium oxide, manganese oxide, cobalt oxide, ruthenium oxide, or combinations thereof.

In certain examples, the active catalyst composition being deposited specifically includes iridium oxide (IrOx).

In alternative examples, the active catalyst composition includes a mixture of iridium oxide and at least one other metal oxide. The at least one other metal oxide may include transition metal oxides such as manganese oxide, cobalt oxide, ruthenium oxide, or combinations thereof. In some embodiments, the mixture of IrOx and the at least one other metal oxide is deposited via ALD via an alternation of layers of the different metal oxides (e.g., alternating between one layer of IrOx and another layer of the at least one additional metal oxide).

The process of ALD of the active catalyst onto the supporting substrate may include the deposition of a thin, continuous nanometer-thick film onto the supporting substrate. This may be advantageous in providing a catalyst film that is dense as opposed to discontinuous films while having a high surface area, being fully oxidized, and electrically active.

In certain alternative embodiments, the process of ALD of the active catalyst on the supporting substrate may include a deposition of the active catalyst in islands on the surface of the substrate (e.g., wherein a single continuous layer of catalyst is not present, but separate clusters of catalyst are present on the surface being separate from each other). These islands or clusters of separate catalyst locations on the surface of the substrate may be interspersed islands of a same active catalyst composition (e.g., IrOx clusters/islands) or different active catalyst compositions (e.g., some segments of IrOx and other separate segments of another metal oxide as described herein).

This process of depositing active catalyst on a substrate via ALD (or alternatively chemical vapor deposition) may advantageously provide an improved electrochemical cell having a lower or reduced active catalyst loading while maintaining or improving the electrical transport to the catalyst. For example, the overall catalyst loading within a cell may be reduced by a factor of 5 or a factor of 10 using this technique without a loss in performance. In other words, the amount of active catalyst such as IrOx loaded or deposited onto the substrate via ALD may be reduced from 2 mg catalyst per cm² of substrate to 0.2 mg/cm².

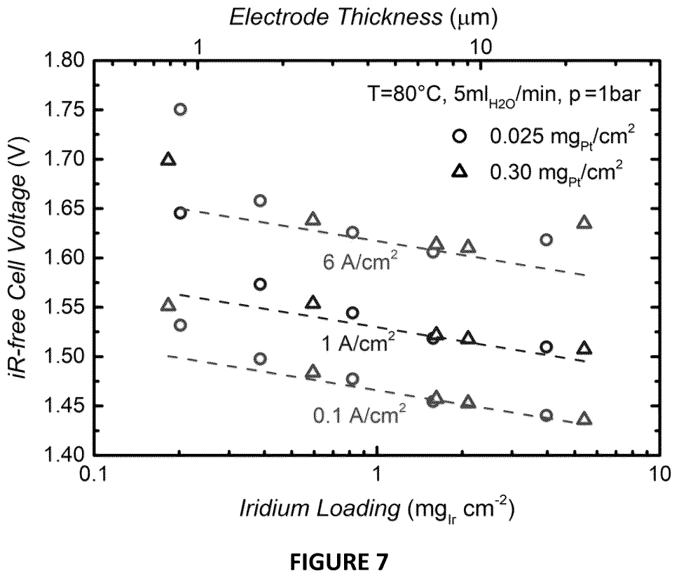

FIG. 7 depicts various examples of IrOx loading curves. The curves depict the amount of iridium being deposited or loaded onto the surface of a substrate in terms of weight (milligrams) of iridium versus area (cm²) of substrate. Performance characteristics are identified for such catalyst loadings.

Additionally, deposition of the active catalyst onto the surface of the substrate may also advantageously allow for a fully oxidized catalyst film to be deposited onto the surface. This may be advantageous in avoiding subsequent processing acts to post-oxidize the catalyst composition, potentially wherein only a partial oxidation is possible.

### Substrate/Core Compositions

In certain examples, the substrate or core is a conductive or semi-conductive composition. A conductive composition refers to a composition having a high electrical conductivity while a semi-conductive composition refers to a composition having an electrical conductivity that is greater than the conductivity of an insulator but less than the conductivity of a good conductor/conductive composition.

In some examples, the substrate or core is a microporous substrate. This may be advantageous in creating an increased surface area of active catalyst being deposited onto the substrate due to the underlying porosity of the substrate. That is, a continuous nanometer-thick film coating of active catalyst deposited on the surface of the porous substrate may have a higher surface area of active catalyst versus a similarly-thick active catalyst deposit on a non-porous substrate material.

Possible compositions of the substrate or core include conductive metal oxides, titanium, or a combination thereof. Non-limiting examples of such conductive metal oxides include chromium(IV) oxide, titanium dioxide, indium tin oxide, fluorine tin oxide, zinc oxide, or combinations thereof. In alternative examples, the conductive core may be made from titanium nanowires.

In some examples, the metal oxides may be doped with an additional metal compound (e.g., tungsten (W) or aluminum (Al). For example, the substrate or core may be a tungsten-doped titanium oxide composition or an aluminum-doped zinc oxide composition.

Conductive fibers, such as carbon nanotubes, nanowires of other metals, doped or undoped silicon nanowires, nanofibers of conductive polymers, or combinations thereof could also be provided as core materials or substrates. In certain examples, the nanofibers of conductive polymers may include polyaniline, poly(3,4-ethylenedioxythiophene) (PEDOT), or a combination thereof.

These other conductive fibers may be used in other applications such as CO₂ reduction cells, NH₃ production cells, or even fuel cells. In all cases, the judicious choice of core material given the intended operation conditions allows for the conduction of electrons through the fiber matrix while maximizing the efficient use of precious metals in the shell deposited by ALD.

These substrate or conductive core materials may be electrospun one-dimensional (“1-D”) nano-fibers, and long, high molecular weight conjugated organic conductive molecules. Such fibers, when cast as a catalyst layer from an ink (a suspension of catalyst particles in a carrier and binder) form a tightly interconnected network of fibers (like a “felt” of fiber particles) that provide for electron conduction across fibers, at a length scale much greater than the individual fiber length. Such structures are highly advantageous as they greatly expand the active area for interaction between electrons, catalyst, and chemical species, especially laterally between the macroscopic metallic contacts (e.g., the anode or the cathode). When this lateral charge transport is poor (as in most catalyst layers, and especially at high area current densities), the catalyst utilization is compromised and the effective accessible active area for electrochemical catalysis is reduced.

### Advantages of Catalyst Compositions

In PEM electrolyzers, hydrogen crossover is a concern as it may result in hazardous combinations of oxygen and hydrogen gases. One configuration of interspersed islands of catalysts could be islands of the active oxygen evolution catalyst (e.g., iridium oxide) and a hydrogen oxidation catalyst (e.g., platinum) to scavenge any hydrogen gas crossing through the PEM, both applied to the same support substrate.

By depositing an active oxygen evolution catalyst via atomic layer deposition onto a support structure such as an electrically conductive wire, the amount of free/available active catalyst surface area may be maximized while minimizing the total catalyst volume used. That is, atomic layer deposition onto a conductive support/core may maximize the surface to volume ratio of the active catalyst being provided. One benefit of this process is that the available catalyst surface area is greatly increased, thereby maximizing the catalyst activity, and minimizing many of the known catalyst degradation mechanisms. An additional benefit of the proposed technique is that ALD films may exhibit exceedingly strong adhesion to a properly prepared substrate surface, thereby inhibiting early degradation.

Another advantage of the solution is that many catalyst production methods have poor utilization of catalyst precursors. Powder ALD has excellent precursor utilization owing to the extremely high surface area of the powder being coated relative to the parasitic surface area of the deposition chamber and associated plumbing. Furthermore, capture and recycling of unutilized ALD precursors is well known and may result in a high net-utilization of rare metals.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, are apparent to those of skill in the art upon reviewing the description.

As used herein, the singular forms “a,” “an,” and “the” include plural referents unless the context clearly dictates otherwise.

As used herein, “for example,” “for instance,” “such as,” or “including” are meant to introduce examples that further clarify more general subject matter. Unless otherwise expressly indicated, such examples are provided only as an aid for understanding embodiments illustrated in the present disclosure and are not meant to be limiting in any fashion. Nor do these phrases indicate any kind of preference for the disclosed embodiment.

The Abstract of the Disclosure is provided to comply with 37 C.F.R. § 1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

It is intended that the foregoing detailed description be regarded as illustrative rather than limiting and that it is understood that the following claims including all equivalents are intended to define the scope of the disclosure. The claims should not be read as limited to the described order or elements unless stated to that effect. Therefore, all embodiments that come within the scope and spirit of the following claims and equivalents thereto are claimed as the disclosure.

1. A method of depositing an active catalyst composition on a substrate, the method comprising:
providing a supporting substrate comprising an electrospun fibrous nanowire, wherein the electrospun fibrous nanowire comprises tungsten doped titanium dioxide; and
depositing an active catalyst composition onto a surface of the supporting substrate via atomic layer deposition (ALD),
wherein the active catalyst composition comprises iridium oxide.

2. The method of claim 1, wherein the supporting substrate is a conductive substrate.

3.-5. (canceled)

6. The method of claim 2, wherein the conductive substrate further comprises carbon nanotubes, silicon nanowires, nanofibers of conductive polymers, or combinations thereof.

7. The method of claim 6, wherein the conductive polymers comprise polyaniline, poly(3,4-ethylenedioxythiophene) (PEDOT), or a combination thereof.

8.-10. (canceled)

11. The method of claim 1, wherein the active catalyst composition is deposited in islands comprising separate catalyst locations on the surface of the supporting substrate.

12. The method of claim 11, wherein a thickness of a layer of the active catalyst composition deposited on the surface of the supporting substrate is in a range of 0.1-100 nm.

13. A catalyst composition comprising:
a conductive substrate comprising an electrospun fibrous nanowire, wherein the electrospun fibrous nanowire comprises tungsten doped titanium dioxide; and
an active catalyst deposited on a surface of the conductive substrate,
wherein the active catalyst comprises iridium oxide.

14.-16. (canceled)

17. The composition of claim 13, wherein the conductive substrate further comprises carbon nanotubes, silicon nanowires, nanofibers of conductive polymers, or combinations thereof.

18. The composition of claim 17, wherein the conductive polymers comprise polyaniline, poly(3,4-ethylenedioxythiophene) (PEDOT), or a combination thereof.

19.-21. (canceled)

22. The composition of claim 13, wherein the active catalyst is deposited in islands comprising separate catalyst locations on the surface of the conductive substrate.

23. The composition of claim 13, wherein a thickness of a layer of the active catalyst deposited on the surface of the conductive substrate is in a range of 0.1-100 nm.
